(19) United States
(12) Patent Application Publication
(10) Pub. No.: US 2015/0318860 A1
(43) Pub. Date: Nov. 5, 2015

(54) LOW NOISE PHASE LOCKED LOOPS

(71) Applicant: QUALCOMM Incorporated, San Diego, CA (US)

(72) Inventors: Shen WANG, Palo Alto, CA (US); Jeongsik YANG, San Jose, CA (US); Thinh Cat NGUYEN, San Jose, CA (US); Ara BICAKCI, Belmont, CA (US); Anup SAVLA, Santa Clara, CA (US)

(73) Assignee: QUALCOMM Incorporated, San Diego, CA (US)

(21) Appl. No.: 14/266,730

(22) Filed: Apr. 30, 2014

(51) Int. Cl. H03L 7/099; H03L 7/093; H03L 7/089

(52) U.S. Cl. CPC H03L 7/0992; H03L 7/0891; H03L 7/093; H03L 2207/05

(57) ABSTRACT

Aspects of circuits and methods for generating an oscillating signal are disclosed. The circuit includes a phase detector configured to output first and second signals responsive to a phase difference between two input signals. The phase detector is further configured to disable the first signal when outputting the second signal and to disable the second signal when outputting the first signal. The circuit further includes a voltage controlled oscillator (VCO) configured to generate an oscillating signal having a tunable frequency responsive to the first and second signals.

### BACKGROUND

1. Field

The present disclosure relates generally to electronic circuits, and more particularly, to low noise phase locked loops.

2. Background

A wireless device (e.g., a cellular phone or a smartphone) may transmit and receive data for two-way communication with a wireless communication system. The wireless device may include a transmitter for data transmission and a receiver for data reception. For data transmission, the transmitter may modulate a local oscillator (LO) signal with data to obtain a modulated radio frequency (RF) signal, amplify the modulated RF signal to obtain an output RF signal having the desired output power level, and transmit the output RF signal via an antenna to a remote device. For data reception, the receiver may obtain a received RF signal via the antenna, amplify and downconvert the received RF signal with an LO signal, and process the downconverted signal to recover data sent by the remote device.

Voltage-controlled oscillators (VCOs) are often used to generate the LO signals. A VCO is an oscillator whose frequency is controlled by a voltage input. A phase locked loop is often be used to adjust the input voltage of the VCO to tune the transmitter or receiver. The phase locked loop is generally implemented with a phase detector that compares the phase of the VCO output with the phase of a reference signal and adjusts the voltage input to the VCO to keep the phases aligned. The ability of the phase locked loop to accurately maintain the phase alignment between the reference signal and the VCO output depends in part on the noise generated in the VCO. A common challenge among skilled artisans in designing phase locked loops is noise reduction.

### SUMMARY

Aspects of a circuit for generating an oscillating signal are disclosed. The circuit includes a phase detector configured to output first and second signals responsive to a phase difference between two input signals. The phase detector is further configured to disable the first signal when outputting the second signal, and to disable the second signal when outputting the first signal. The circuit also includes a voltage controlled oscillator (VCO) configured to generate an oscillating signal having a tunable frequency responsive to the first and second signals.

Aspects of a circuit for generating an oscillating signal are disclosed. The circuit includes means for detecting a phase difference between two input signals. The means for detecting a phase difference is configured to output first and second signals responsive to the phase difference between two input signals. The means for detecting a phase difference is further configured to disable the first signal when outputting the second signal, and to disable the second signal when outputting the first signal. The circuit also includes means for generating an oscillating signal having a tunable frequency responsive to the first and second signals.

Aspects of a method of generating an oscillating signal are disclosed. The method includes detecting a phase difference between two input signals. The detecting of the phase difference includes outputting first and second signals responsive to the phase difference between two input signals by disabling the first signal when outputting the second signal and to disabling the second signal when outputting the first signal. The method also includes generating an oscillating signal having a tunable frequency responsive to the first and second signals.

It is understood that other aspects of apparatus, circuits and methods will become readily apparent to those skilled in the art from the following detailed description, wherein various aspects of apparatus, circuits and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus, circuits and methods will now be presented in the detailed description by way of example, and not by way of limitation, with reference to the accompanying drawings, wherein:

FIG. 1 is a conceptual block diagram illustrating an exemplary embodiment of a wireless device.

FIG. 2 is a block diagram illustrating an exemplary embodiment of a wireless transceiver.

FIG. 3 is a functional block diagram illustrating an exemplary embodiment of a phase locked loop for a local oscillator.

FIG. 4A is a functional block diagram illustrating an exemplary embodiment of a phase locked loop for a local oscillator with additional schematic details for the charge pump and loop filter.

FIG. 4B is a functional block diagram illustrating an exemplary embodiment of a phase locked loop for the local oscillator of FIG. 4A with the addition of a leakage current source in the charge pump.

FIG. 5 is a functional block diagram illustrating an exemplary embodiment of a phase detector for a phase locked loop.

FIG. 6A is a timing diagram illustrating the operation of the exemplary embodiment of the phase detector of FIG. 5 when the reference signal leads the feedback signal.

FIG. 6B is a timing diagram illustrating the operation of the exemplary embodiment of the phase detector of FIG. 5 when the reference signal trails the feedback signal.

FIG. 7 is a functional block diagram illustrating an alternative exemplary embodiment of a phase detector for a phase locked loop.

FIG. 8 is a flow chart illustrating an exemplary method of generating an oscillating signal.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus, circuit or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the terms “comprises”, “comprising,”, “includes” and/or “including”, when used herein, specify the presence of the stated features, integers, steps, operations, elements, and/or components, but do not preclude the presence or addition of one or more other features, integers, steps, operations, elements, components, and/or groups thereof.

Various aspects of phase locked loops for tuning the frequency of transmitters and receivers in wireless devices will now be presented. However, as those skilled in the art will readily appreciate, such aspects may be extended to other circuit configurations and devices. By way of example, various aspects of the present invention may be used for signal recovery in a noisy channel, frequency synthesis, clock distribution, and other suitable uses that require a phase locked loop or similar circuit. According all references to a specific application for a phase locked loop, or any component, structure, feature, functionality, or process within a phase locked loop are intended only to illustrate exemplary aspects of a phase locked loop with the understanding that such aspects may have a wide differential of applications.

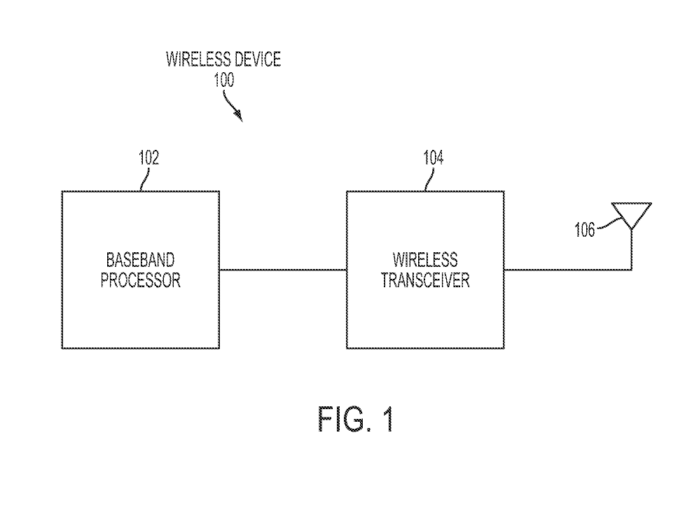

Various embodiments of a phase locked loop may be used in a wireless device, such as a mobile phone, personal digital assistant (PDA), desktop computer, laptop computer, palm-sized computer, tablet computer, set-top box, navigation device, work station, game console, media player, or any other suitable device. FIG. 1 is a conceptual block diagram illustrating an exemplary embodiment of such a wireless device. The wireless device 100 may be configured to support any suitable multiple access technology, including by way of example, Code Division Multiple Access (CDMA) systems, Multiple-Carrier CDMA (MCCDMA), Wideband CDMA (W-CDMA), High-Speed Packet Access (HSPA, HSPA+) systems, Time Division Multiple Access (TDMA) systems, Frequency Division Multiple Access (FDMA) systems, Single-Carrier FDMA (SC-FDMA) systems, Orthogonal Frequency Division Multiple Access (OFDMA) systems, or other multiple access technologies. The wireless device 100 may be further configured to support any suitable air interface standard, including by way of example, Long Term Evolution (LTE), Evolution-Data Optimized (EV-DO), Ultra Mobile Broadband (UMB), Universal Terrestrial Radio Access (UTRA), Global System for Mobile Communications (GSM), Evolved UTRA (E-UTRA), IEEE 802.11 (Wi-Fi), IEEE 802.16 (WiMAX), IEEE 802.20, Flash-OFDM, Blueooth, or any other suitable air interface standard. The actual air interface standard and the multiple access technology supported by the wireless device 100 will depend on the specific application and the overall design constraints imposed on the system.

The wireless device 100 includes a baseband processor 102, a wireless transceiver 104, and an antenna 106. The wireless transceiver 104 may employ various aspects of phase locked loops presented throughout this disclosure to generate one or more LO signals to support both a transmitting and receiving function. The wireless transceiver 104 performs the transmitting function by modulating one or more carrier signals with a data generated by the baseband processor 102 for transmission over a wireless channel through the antenna 106. The wireless transceiver 104 performs a receiving function by demodulating one or more carrier signals received from the wireless channel through the antenna 106 to recover data for further processing by the baseband processor 102. The baseband processor 102 provides the basic protocol stack required to support wireless communications, including for example, a physical layer for transmitting and receiving data in accordance with the physical and electrical interface to the wireless channel, a data link layer for managing access to the wireless channel, a network layer for managing source to destination data transfer, a transport layer for managing transparent transfer of data between end users, and any other layers necessary or desirable for establishing or supporting a connection to a network through the wireless channel.

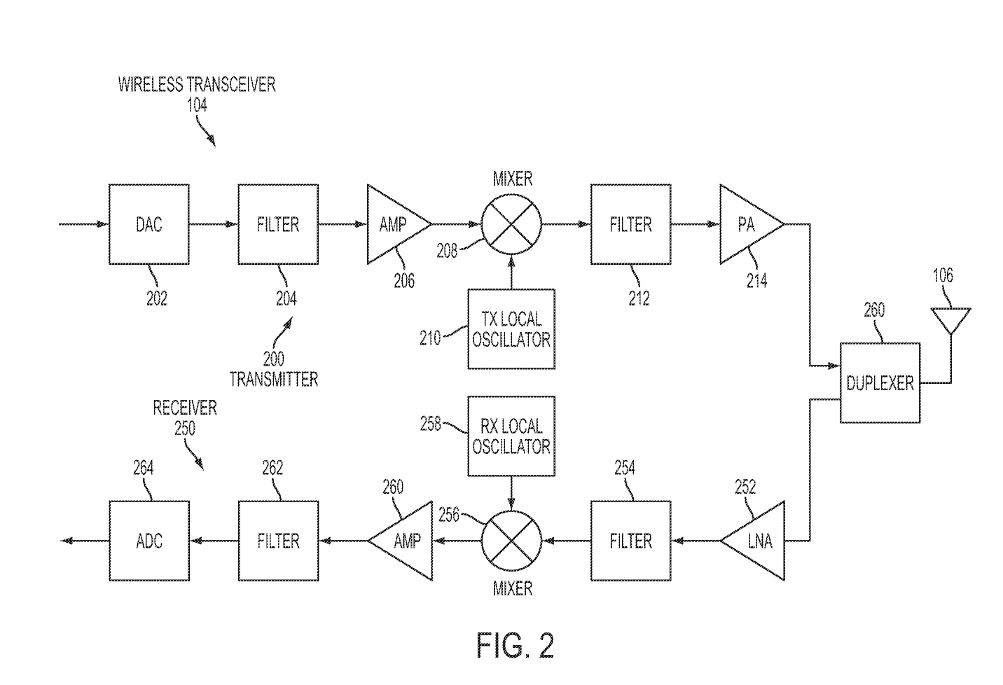

FIG. 2 is a block diagram of an exemplary embodiment of a wireless transceiver. The wireless transceiver 104 includes a transmitter 200 and a receiver 250 that support bi-directional communication. The transmitter 200 and/or the receiver 250 may be implemented with a super-heterodyne architecture or direct-conversion architecture. In the super-heterodyne architecture, a signal is frequency converted between RF and baseband in multiple stages (e.g., from RF to an intermediate frequency (IF) in one stage, and then from IF to baseband in another stage for a receiver). In the direct-conversion architecture, which is also referred to as a zero-IF architecture, a signal is frequency converted between RF and baseband in one stage. The super-heterodyne and direct-conversion architectures may use different circuit blocks and/or have different requirements. In the exemplary embodiment shown in FIG. 2, the transmitter 200 and the receiver 250 are implemented with a direct-conversion architecture.

In the transmit path, the baseband processor 104 (see FIG. 1) provides data to a digital-to-analog converter (DAC) 202. The DAC 202 converts a digital input signal to an analog output signal. The analog output signal is provided to a filter 204, which filters the analog output signal to remove images caused by the prior digital-to-analog conversion by the DAC 202. An amplifier 206 is used to amplify the signal from the filter 204 to provide an amplified baseband signal. A mixer 208 receives the amplified baseband signal and an LO signal from TX local oscillator 210. The mixer 208 mixes the amplified baseband signal with the LO signal to provide an upconverted signal. A filter 212 is used to filter the upconverted signal to remove images caused by the frequency mixing. A power amplifier (PA) 214 is used to amplify the signal from the filter 212 to obtain an output RF signal at the desired output power level. The output RF signal is routed through a duplexer 260 to the antenna 106 for transmission over the wireless channel.

In the receive path, the antenna 106 may receive signals transmitted by a remote device. The received RF signal may be routed through the duplexer 260 to the receiver 250. Within the receiver 250, the received RF signal is amplified by a low noise amplifier (LNA) 252 and filtered by a filter 254 and to obtain an input RF signal. A mixer 256 receive the input RF signal and an LO signal from a RX local oscillator 258. The mixer 256 mixes the input RF signal with the LO signal to provide a downconverted signal. The downconverted signal is amplified by an amplifier 260 to obtain an amplified downconverted signal. A filter 262 is used to filter the amplified downconverted signal to remove images caused by the frequency mixing. The signal from the filter 262 is provided to an analog-to-digital converter (ADC) 264. The ADC 264 converts the signal to a digital output signal. The digital output signal may be provided to the baseband processor 104 (see FIG. 1).

The conditioning of the signals in the transmitter 200 and the receiver 250 may be performed by one or more stages of amplifiers, filters, mixers, etc. These circuits may be arranged differently from the configuration shown in FIG. 2. Furthermore, other circuits not shown in FIG. 2 may also be used to condition the signals in the transmitter 200 and the receiver 250. For example, impedance matching circuits may be located at the output of the PA 216, at the input of the LNA 252, between the antenna 106 and the duplexer 260, etc.

Various embodiments of local oscillators may be used to support transmitter and receiver functions. In one exemplary embodiment, the local oscillator may be implemented with a VCO that provides the LO signal to the transmitter and/or receiver for mixing. A VCO is a positive feedback amplifier that has a tuned resonator in the feedback loop. Oscillations occur at the resonant frequency, which can be tuned by a phase locked loop. The phase locked loop may be implemented with a phase detector that compares the phase of the VCO output with the phase of a reference signal and tunes the resonator of the VCO to keep the phases aligned.

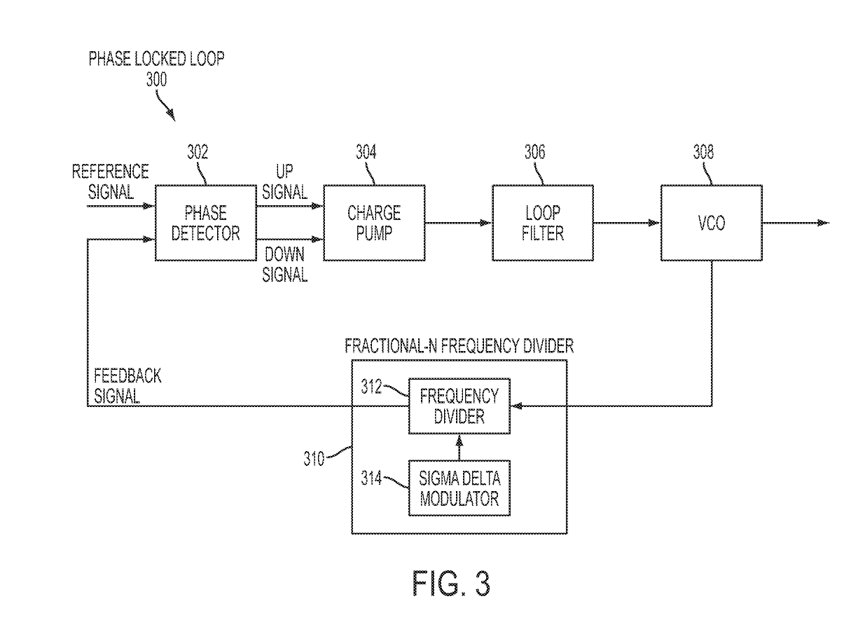

FIG. 3 is a functional block diagram illustrating an exemplary embodiment of a phase locked loop for a local oscillator. In this embodiment, the local oscillator is implemented with a phase locked loop 300. The phase-locked loop 300 includes a phase detector 302, a charge pump 304, a loop filter 306, a VCO 308, and a fractional-N frequency divider 310 having a frequency divider 312 and a sigma delta modulator 314. The phase detector 302 provides a means for detecting a phase difference between two input signals. It is used to detect a phase error between a reference signal and a feedback signal from the fractional-N frequency divider 310. The phase detector 302 generates UP and DOWN signals based on the phase error. The UP and DOWN signals are used to drive the charge pump 304. The charge pump 304 provides a means for providing a current source to the loop filter 306. It injects a charge proportional to the detected phase error into the loop filter 306. The loop filter 306 provides a means for generating a control voltage for tuning the VCO 308. It integrates the output from the charge pump 304 to generate a control voltage that is input to the VCO 308. The VCO 308 provides a means for generating an oscillating signal having a tunable frequency. It generates an oscillating signal whose frequency is proportional to the control voltage generated by the loop filter 306. The fractional N-frequency divider 310 provides a means for generating the feedback signal by fractionally dividing the frequency of the oscillating signal. It includes the frequency divider 312 which divides the frequency of the VCO output by an integer N to produce the feedback signal input to the phase detector. It also includes the delta-sigma modulator 314 that dynamically switches the value of N during the locked state to realize an average divider which is a non-integer between N and N+1.

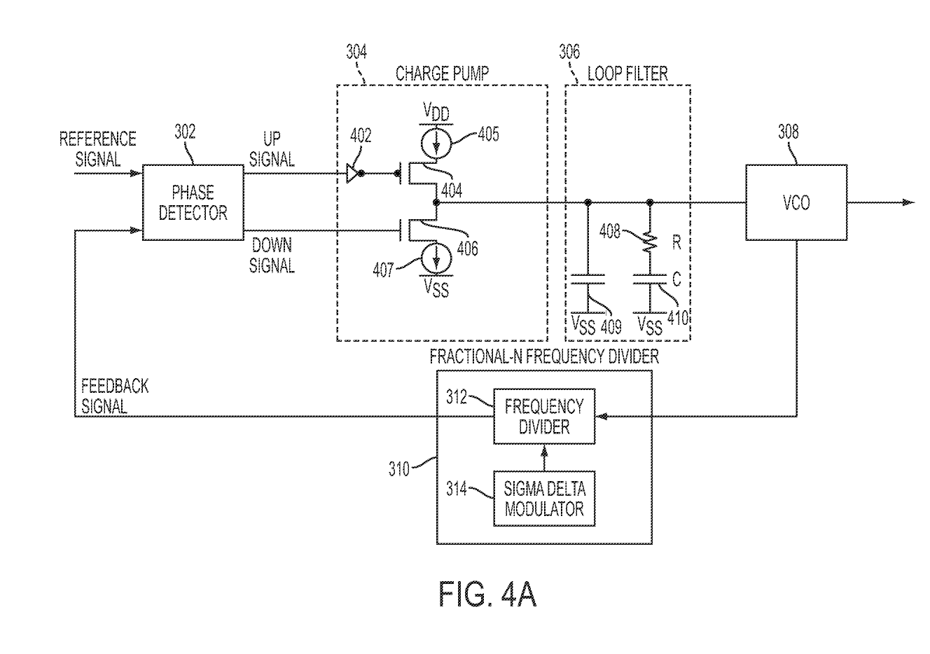

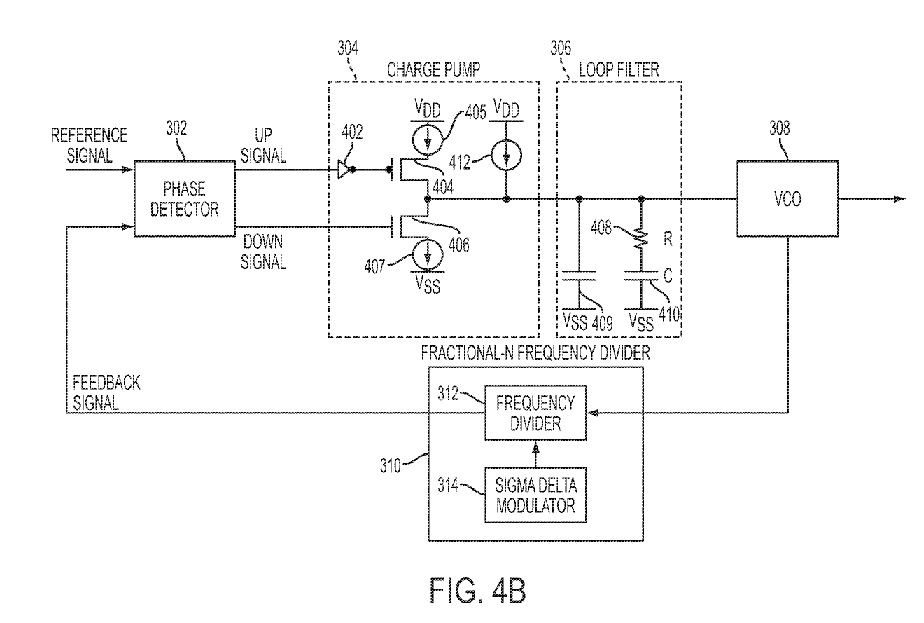

FIG. 4A is a functional block diagram illustrating an exemplary embodiment of a phase locked loop for a local oscillator with additional schematic details for the charge pump and loop filter. As described above, the phase detector 302 compares the reference signal to the feedback signal from the fractional-N frequency divider 310 and activates the charge pump 304 based on the phase difference between the two signals. The phase detector 302 operates in a phase detection mode and a phase locked state. For this reason, the phase detector is sometimes referred to as a phase/frequency detector (PFD). For the purposes of this disclosure, the term “phase detector” shall be construed broadly to include a component capable of detecting a difference in phase and/or frequency of two input signals.

The phase detector 302 operates in a phase detection mode, in which the duty cycles of the UP and DOWN signals are varied based on the phase error measured by the phase detector 302. As a result, the charge pump 304 is activated for only a portion of the time, which is proportional to the phase difference between the two signals. The loop filter 306 accumulates a charge that produces a filtered control voltage which adjusts the frequency of the VCO output signal until the phase difference reaches zero. Once this occurs, the phase detector 302 enters the phase locked state. In this state, the duty cycles of the UP and DOWN signals are substantially equal, and therefore, no net charge is injected into the loop filter 306. The control voltage input to the VCO 308 remains constant, which ensures that the VCO output signal remains at a constant frequency.

The loop filter 306 may be active or passive. An exemplary embodiment of a passive loop filter 306 is shown in FIG. 4. In this embodiment, the loop filter 306 comprises a first order loop filter comprising a resistor R 408 and capacitor C 410 connected in series between the charge pump 304 output and the negative supply voltage V_{SS} (e.g., ground). Alternative embodiments of a loop filter may also be employed. For example, the loop filter 306 may include an extra pole capacitor 409 connected in parallel to the resistor R 408 and capacitor C 410.

The charge pump 304 may also be implemented in several ways. In one exemplary embodiment, the charge pump 304 is implemented with a first switch 404 that provides a means for sourcing a charge current to the loop filter 306 and a second switch 406 that provides a means for sinking a discharge current from the loop filter 306. The first switch 404 may be a PMOS transistor and the second switch 406 may be an NMOS transistor 406. The PMOS transistor is connected to the positive supply voltage V_{DD}, via a current source 405. The NMOS transistor is connected to the negative supply voltage V_{SS}, via a current source 407, as shown FIG. 4A. The current sources 405 and 407 provide a constant current source to the charge pump 304. The UP signal from the phase detector 302 controls the PMOS transistor 404 through an inverter 402 and the DOWN signal from the phase detector 302 controls the NMOS transistor. When the UP signal is driven by the phase detector 302 to a high logic level state, the capacitor C 410 in the loop filter 306 is charged through the PMOS transistor 404. When the DOWN signal is driven by the phase detector 202 to a high logic level state, the capacitor C 410 in the loop filter 306 is discharged through the NMOS transistor 406. An extra pole capacitor 409 may be added in parallel with the resistor R 408 and capacitor C 410 to further adjust the loop filter 306.

FIG. 4B is a functional block diagram illustrating an exemplary embodiment of a phase locked loop for the local oscillator of FIG. 4A with the addition of a leakage current source in the charge pump. The leakage current source provides a means for providing a leakage current to the loop filter 306. In this embodiment, a leakage current source 410 is used to avoid noise folding of the delta-sigma modulator at close-in offset frequencies which would otherwise occur due to the nonlinearity of the charge pump 302 in a fractional-N phase locked loop. The leakage current source 412 may be implemented with one or more transistors with appropriate biasing or by other suitable means. The leakage current source 410 causes a constant average phase difference between the reference and feedback signals input to the phase detector 302 in the locked state. As a result, one of the UP or DOWN signals always has a higher duty cycle than the other depending on how the leakage current is implemented. In some embodiments, the narrower pulse may be driven to a continuous “low” logic state while the wider pulse maintains a width equal to the phase difference. With this approach, there is no switching of the current sources in the charge pump 302, thereby reducing noise.

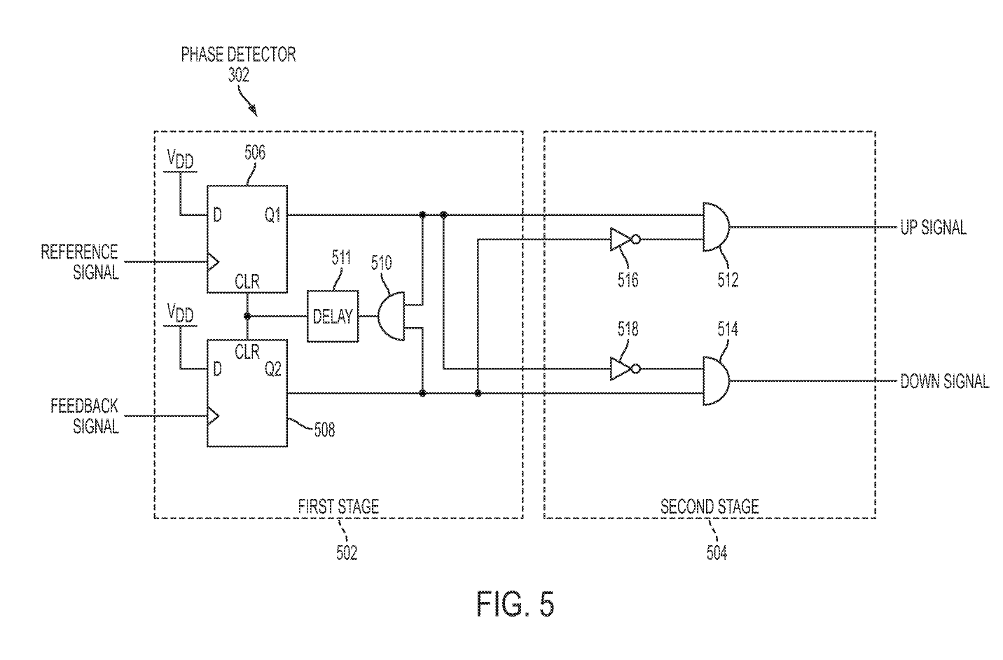

FIG. 5 is a functional block diagram illustrating an exemplary embodiment of a phase detector for a phase locked loop. In this embodiment, the phase detector 302 includes two stages: a first stage 502 and a second stage 504. The first stage 502 generates UP and DOWN signals based on the phase difference between the reference signal and the feedback signal. The second stage 504 drives either UP signal or DOWN signal to a low logic state depending on which signal has the lower duty cycle.

The first stage 502 includes a first flip-flop 506, a second flip-flop 508, a reset gate 510, and a delay 511. In this embodiment, both flip-flops 506 and 508 are D flip-flops and the reset gate 510 is an AND gate, however, other flip-flops, gates, and/or components may be used, added, and/or omitted in alternative embodiments. The inputs to both flip-flops 506 and 508 are pulled up to V_{DD} (i.e., a high logic state). The reference signal is used to clock the first flip-flop 506 and the feedback is used to clock the second flip-flop 508. As a result, the output Q1 of the first flip-flop 506 is driven to a high logic state when the reference signal transitions to a high logic state and output Q2 of the second flip-flop 508 is driven to a high logic state with the feedback signal transitions to a high logic state. The reset gate 510 is used to provide an “AND” function for the two outputs from the flip-flops 506 and 508. The output from the reset gate 510 is used to reset both the flip-flops 506 and 508 once both the outputs from the flip-flops 506 and 508 enter a high logic state after a suitable delay.

The second stage 504 includes a gating circuit comprising a first gate 512, a second gate 514, a first inverter 516, and a second inverter 518. The first gate 512 is used to generate the UP signal and a second gate 514 is used to generate the DOWN signal. In one embodiment, both gates 512 and 514 are AND gates, but may be implemented differently in alternative embodiments. For example, each gate may be alternatively implemented as a NAND gate followed by an inverter or by other suitable means. Each gate 512 and 514 functions to pass the signal at a first input to the output when the second input is in a high logic state. Thus, the second input to each gate 512 and 514 can be viewed as an enable signal. That is, each gate 512 and 514 passes the signal at the first input to the output when the enable signal is in a high logic state. When the enable signal is in a low logic state, the output is forced low regardless of the state of the first input. First and second inverters 516 and 518 are used to generate the enable signal. Specifically, the first inverter 516 is used to generate the enable signal to the first gate 512, and the second inverter 518 is used to generate the enable signal to the second gate 514. In the described embodiment, the enable signal for the first gate 512 is the inverted output Q2 of the second flip-flop 508, and the enable signal for the second gate 514 is the inverted output Q1 of the first flip-flop 506.

In operation, the output Q1 from the first flip-flop 506 is passed through the first gate 512 as the UP signal when the output Q2 from the second flip-flop 508 is in a low logic state. When the output Q2 from the second flip-flop 508 is in a high logic state, the UP signal output from the first gate 512 is forced into a low logic state. Similarly, the output Q2 from the second flip-flop 508 is passed through the second gate 514 as the DOWN signal when the output Q1 from the first flip-flop 506 is in a low logic state. When the output Q1 from the first flip-flop 506 is in a high logic state, the DOWN signal output from the second gate 514 is forced into a low logic state.

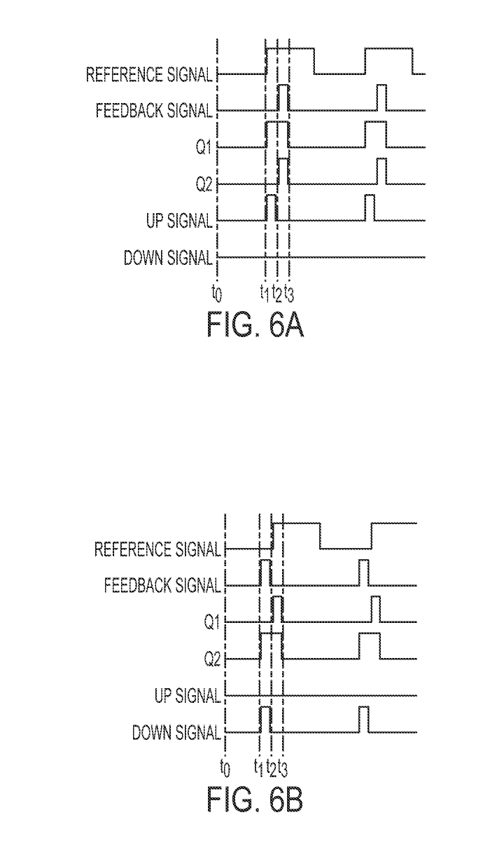

FIGS. 6A and 6B are timing diagrams illustrating the operation of the exemplary embodiment of the phase locked loop of FIG. 5. FIG. 6A shows the timing of the phase detector when the reference signal leads the feedback signal from the frequency divider. FIG. 6B shows the timing of the phase detector when reference signal trails the feedback signal.

Referring to FIGS. 5 and 6A, both the output Q1 from the first flip-flop 506 and the output Q2 from the second flip-flop 508 are in a low logic state at t₀. As a result, both of the first and second gates 512 and 514 are enabled by the inverted flip-flop outputs Q1 and Q2 from inverters 516 and 518, respectively. With the first gate 512 enabled, the low logic state output Q1 from the first flip-flop 506 is passed through the first gate 512 to the output to produce an UP signal in a low logic state. With the second gate 514 enabled, the low logic state output Q2 from the second flip-flop 506 is passed through the second gate 514 to the output to produce a DOWN signal in a low logic state.

At t₁, the reference signal transitions from a low logic state to a high logic state, thereby setting the output Q1 of the first flip-flop 506 to a high logic state. The high logic state is passed through the first gate 512 to the output to drive the UP signal to a high logic state. At the same time, the inverted flip-flop output Q1 from the 1 second inverter 518 transitions to a low logic state, thereby disabling the second gate 514.

At t₂, the feedback signal transitions from a low logic state to a high logic state, thereby setting the output Q2 of the second flip-flop 508 to a high logic state. Since the second gate 514 is disabled, the high logic state of the output Q2 from the second flip-flop 508 is not passed through the second gate 514. As a result, the DOWN signal remains in a low logic state. The inverted flip-flop output Q2 from the first inverter 516 transitions to a low logic state, thereby disabling the first gate 512 and forcing the UP signal into a low logic state. With both outputs Q1 and Q2 in a high logic state, the output from the reset gate 510 transitions to a high logic state and resets both flip-flops 506 and 508 after a suitable delay at t₃. With both flip-flops 506 and 508 reset, the inverted flip-flop outputs Q1 and Q2 from inverters 516 and 518 are driven to a high logic state, thereby enabling both the first and second gates 512 and 514 for the next cycle. This process continues until the phase locked loop achieves a lock by aligning the feedback signal with the reference signal.

Referring to FIGS. 5 and 6B, both the output Q1 from the first flip-flop 506 and the output Q2 from the second flip-flop 508 are in a low logic state at t₀. As a result, both of the first and second gates 512 and 514 are enabled by the inverted latch outputs Q1 and Q2 from inverters 516 and 518, respectively. With the first gate 512 enabled, the low logic state output Q1 from the first flip-flop 506 is passed through the first gate 512 to the output to produce an UP signal in a low logic state. With the second gate 514 enabled, the low logic state output Q2 from the second flip-flop 506 is passed through the second gate 514 to the output to produce a DOWN signal in a low logic state.

At t₁, the feedback signal transitions from a low logic state to a high logic state, thereby setting the output Q2 of the second flip-flop 508 to a high logic state. The high logic state is passed through the second gate 514 to the output to drive the DOWN signal to a high logic state. At the same time, the inverted flip-flop output Q2 from the first inverter 516 transitions to a low logic state, thereby disabling the first gate 512.

At t₂, the reference signal transitions from a low logic state to a high logic state, thereby setting the output Q1 of the first flip-flop 506 to a high logic state. Since the first gate 512 is disabled, the high logic state of the output Q1 from the first flip-flop 506 is not passed through the first gate 512. As a result, the UP signal remains in a low logic state. The inverted flip-flop output Q1 from the second inverter 518 transitions to a low logic state, thereby disabling the second gate 514 and forcing the DOWN signal into a low logic state. With both outputs Q1 and Q2 in a high logic state, the output from the reset gate 510 transitions to a high logic state and resets both flip-flops 506 and 508 after a suitable delay at t₃. With both flip-flops 506 and 508 reset, the inverted flip-flop outputs Q1 and Q2 from inverters 516 and 518 are driven to a high logic state, thereby enabling both the first and second gates 512 and 514 for the next cycle. This process continues until the phase locked loop achieves a lock by aligning the feedback signal with the reference signal.

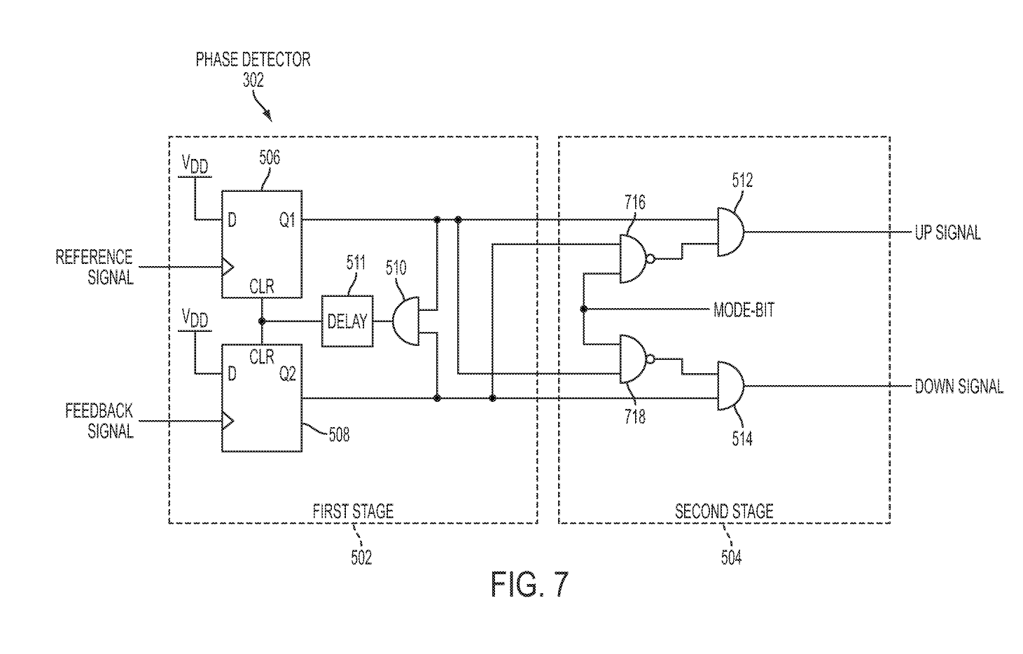

FIG. 7 is a functional block diagram illustrating an alternative exemplary embodiment of a phase detector for a phase locked loop. In this embodiment, the inverters in the second stage are replaced with NAND gates. Specifically, the first inverter 516 (see FIG. 5) is a replaced with a first NAND gate 716 and the second inverter 518 (see FIG. 5) is replaced with a second NAND gate 718. The NAND gates 716 and 718 allow a mode-bit to switch the phase detector 302 between two different modes of operation. With the mode-bit set to a high logic state, the NAND gates 716 and 718 function as inverters with the operation of the phase detector being the same as described above in connection with FIGS. 5, 6A and 6B. With the mode-bit driven to a low logic state, the outputs from both NAND gates 716 and 718 are always in a high logic state regardless of the state of the outputs Q1 and Q2 of the first and second flip-flops 506 and 508, respectively. As a result, the first and second gates 512 and 514 are always enabled. With both gates 512 and 514 enable, the UP signal follows the output Q1 from the first flip-flop 506 and the DOWN signal follows the output Q2 from the second flip-flop 508. In this mode, both the UP and DOWN signals will be pulsed each cycle.

In the exemplary embodiments of a phase detector described thus far, the UP or DOWN signal with the lower duty cycle is gated off (i.e., forced to a low logic state). However, the signal with the lower duty cycle may be forced to a low logic state by means other than gating. For example, a multiplexer may be used to switch between the UP signal and a low logic state depending on the duty cycle of the UP signal relative to the DOWN signal. Similarly, a multiplexer may be used to switch between the DOWN signal and a low logic state depending on the duty cycle of the DOWN signal relative to the UP signal. Alternatively, in some exemplary embodiments, the UP or DOWN signal with the lower duty cycle may be turned off by driving the signal to a high logic state. Those skilled in the art will be readily able to design various circuit configurations to force the turn off the UP or DOWN signal with the lowest duty cycle depending on the particular application and overall design constraints imposed on the system.

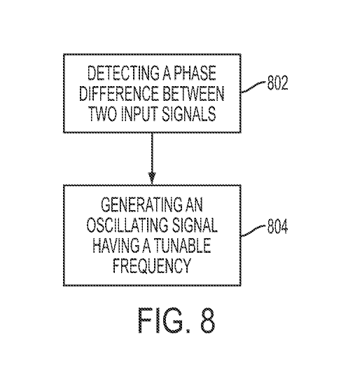

FIG. 8 is a flow chart illustrating an exemplary method of generating an oscillating signal.

The method includes detecting a phase difference between two input signals in block 802. The phase difference may be detected by outputting first and second signals responsive to the phase difference where the first signal is disabled when outputting the second signal and the second signal is disabled when outputting the first signal. In one exemplary embodiment, a gating circuit may be used to disable the first signal when outputting the second signal and to disable the second signal when outputting first signal. The two input signals may comprise a reference signal and a feedback signal. The feedback signal is a function of the oscillating signal. In one exemplary embodiment, the feedback signal may be generated by fractionally dividing the frequency of the oscillating signal.

The method further includes generating an oscillating signal having a tunable frequency responsive to the first and second signals in block 804. A control voltage may be used to tune the frequency of the oscillating signal. A current source may be used to generate the control voltage. The current source may source a charge current in response to the first signal and sink a discharge current in response to the second signal. The control voltage may be generated by integrating the charge and discharge currents. A leakage current source may also be used in the generation of the control voltage.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The previous description is provided to enable any person skilled in the art to fully understand the full scope of the disclosure. Modifications to the various exemplary embodiments disclosed herein will be readily apparent to those skilled in the art. Thus, the claims should not be limited to the various aspects of the disclosure described herein, but shall be accorded the full scope consistent with the language of claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A circuit for generating an oscillating signal, comprising:
a phase detector configured to output first and second signals responsive to a phase difference between two input signals, the phase detector being further configured to disable the first signal when outputting the second signal and to disable the second signal when outputting the first signal;
a voltage controlled oscillator (VCO) configured to generate an oscillating signal having a tunable frequency responsive to the first and second signals.

2. The circuit of claim 1 further comprising a charge pump and a loop filter, wherein the charge pump is configured to provide a current source to the loop filter by sourcing a charge current in response to the first signal and sinking a discharge current in response to the second signal.

3. The circuit of claim 2 wherein the loop filter is configured to integrate the charging and discharging current to generate a control voltage for tuning the frequency of the VCO.

4. The circuit of claim 2 wherein the charge pump further comprises a leakage current source coupled to the loop filter.

5. The circuit of claim 1 wherein the phase detector comprises a gating circuit configured to disable the first signal when outputting the second signal and to disable the second signal when outputting first signal.

6. The circuit of claim 1 wherein the two input signals comprise a reference signal and a feedback signal, the feedback signal being derived from the oscillating signal.

7. The circuit of claim 6 further comprising a fractional-N divider configured to generate the feedback signal from the oscillating signal.

8. A circuit for generating an oscillating signal, comprising:
means for detecting a phase difference between two input signals, wherein the means for detecting a phase difference is configured to output first and second signals responsive to the phase difference between two input signals, and wherein the means for detecting a phase difference is further configured to disable the first signal when outputting the second signal and to disable the second signal when outputting the first signal;
means for generating an oscillating signal having a tunable frequency responsive to the first and second signals.

9. The circuit of claim 8 further comprising means for generating a control voltage for tuning the frequency of the oscillating signal, means for providing a current source to the means for generating a control voltage comprising means for sourcing a charge current in response to the first signal and means for sinking a discharge current in response to the second signal.

10. The circuit of claim 9 wherein the means for generating a control voltage is configured to integrate the charging and discharging current to generate the control voltage for tuning the frequency of the oscillating signal.

11. The circuit of claim 9 wherein the means for providing a current source further comprising means for providing a leakage current to the means for generating a control voltage.

12. The circuit of claim 8 wherein the means for detecting a phase difference comprises a gating circuit configured to disable the first signal when outputting the second signal and to disable the second signal when outputting first signal.

13. The circuit of claim 8 wherein the two input signals comprise a reference signal and a feedback signal, the feedback signal being a function of the oscillating signal.

14. The circuit of claim 13 further comprising means for generating the feedback signal by fractionally dividing the frequency of the oscillating signal.

15. A method of generating an oscillating signal, comprising:
detecting a phase difference between two input signals, the detecting comprising outputting first and second signals responsive to the phase difference between two input signals by disabling the first signal when outputting the second signal and to disabling the second signal when outputting the first signal;
generating an oscillating signal having a tunable frequency responsive to the first and second signals.

16. The method of claim 15 further comprising generating a control voltage for tuning the frequency of the oscillating signal, and providing a current source for generating the control voltage by sourcing a charge current in response to the first signal and sinking a discharge current in response to the second signal.

17. The method of claim 16 wherein the generating of a control voltage comprises integrating the charging and discharging current.

18. The method of claim 16 further comprising providing a leakage current to the generating of a control voltage.

19. The method of claim 15 wherein the detecting of a phase difference comprises using a gating circuit to disable the first signal when outputting the second signal and to disable the second signal when outputting first signal.

20. The method of claim 15 wherein the two input signals comprise a reference signal and a feedback signal, the feedback signal being a function of the oscillating signal.

21. The method of claim 20 further comprising generating the feedback signal by fractionally dividing the frequency of the oscillating signal.
